(19) United States
(12) Patent Application Publication
(10) Pub. No.: US 2022/0077844 A1
(43) Pub. Date: Mar. 10, 2022

(54) INTEGRATION METHOD AND INTEGRATION STRUCTURE FOR CONTROL CIRCUIT AND SURFACE ACOUSTIC WAVE FILTER

(71) Applicant: NINGBO SEMICONDUCTOR INTERNATIONAL CORPORATION (SHANGHAI BRANCH), Shanghai (CN)

(72) Inventor: Xiaoshan QIN, Ningbo, Zhejiang (CN)

(21) Appl. No.: 17/417,947

(22) PCT Filed: Nov. 13, 2019
(86) PCT No.: PCT/CN2019/117791

§ 371 Date: Jun. 24, 2021

(30) Foreign Application Priority Data
Dec. 26, 2018 (CN) 201811601414.4

(51) Int. Cl. H03H 9/64; H03H 9/02; H03H 9/54

(52) U.S. Cl. CPC H03H 9/64; H03H 9/54; H03H 9/02535

(57) ABSTRACT

The present disclosure provides an integration method and integration structure for a control circuit and a Surface Acoustic Wave (SAW) filter. The integration method includes: providing a base, the base being provided with a control circuit; forming a cavity on the base; providing an SAW resonating plate, an input electrode and an output electrode being arranged on a surface of the SAW resonating plate; facing the surface of the SAW resonating plate towards the base, such that the SAW resonating plate is bonded to the base and seals the cavity; and electrically connecting the control circuit to the input electrode and the output electrode. The present disclosure may control the SAW filter through the control circuit provided on the base, and may avoid the problems of the complex electrical connection process, large insertion loss and the like due to a fact that the existing SAW filter is integrated to the Printed Circuit Board (PCB) as a discrete device.

### FIELD OF TECHNOLOGY

The present disclosure relates to the technical field of acoustic wave filters, and in particular to an integration method and integration structure for a control circuit and a Surface Acoustic Wave (SAW) filter.

### BACKGROUND

As an elastic wave, the SAW is produced and propagated on the surface of the piezoelectric plate material and has the amplitude quickly decreased with the increase of a depth penetrated into the plate material. The basic structure of the SAW filter is achieved by manufacturing two acoustoelectric transducers-comb electrode Interdigital Transducers (IDTs) on the plate material with piezoelectric characteristics to respectively serve as a transmitting transducer and a receiving transducer. The working band of the SAW filter is typically 800 MHz to 2 GHz, and the bandwidth is 17 MHz to 30 MHz. With the good selectivity, wide band, stable performance and high reliability, the SAW filter has become the most widely used radio-frequency filter at present.

When packaged, the single SAW filter is typically packaged as a discrete device, and then integrated to a Printed Circuit Board (PCB). For the sake of the use requirement, it is frequent that a plurality of SAWS are integrated on one PCB board. Such a manner that performs independent packaging and then system integration leads to problems of the complex System In Package (SIP) wiring, large insertion loss and the like; and moreover, there is a need to introduce the discrete switch, selection device and control device for controlling the SAW filter, which accelerates both the process complexity and the manufacturing cost.

### SUMMARY

An objective of the present disclosure is to provide an integration method for a control circuit and an SAW filter and a corresponding integration structure, to overcome the problems of the complex SIP wiring, large insertion loss and the like of the existing SAW filter during packaging and integration.

According to an aspect of the present disclosure, an integration method for a control circuit and an SAW filter is provided, which includes:
providing a base, the base being provided with a control circuit;
forming a cavity on the base;
providing an SAW resonating plate, an input electrode and an output electrode being arranged on a surface of the SAW resonating plate;
facing the surface of the SAW resonating plate towards the base, such that the SAW resonating plate is bonded to the base and seals the cavity; and
electrically connecting the control circuit to the input electrode and the output electrode.

Optionally, the base includes a substrate and a first dielectric layer formed on the substrate; and
forming the cavity on the base comprises:
forming the cavity in the first dielectric layer.

Optionally, the substrate includes one of a Silicon-on-Insulator (SOI) substrate, a silicon substrate, a germanium substrate, a germanium silicate substrate and a gallium arsenide substrate.

Optionally, the control circuit includes a device structure and a first interconnection structure layer electrically connected to the device structure, the first interconnection structure layer being located on the first dielectric layer, and electrically connected to the input electrode and the output electrode.

Optionally, the device structure includes a Metal Oxide Semiconductor (MOS) device.

Optionally, electrically connecting the control circuit to the input electrode and the output electrode includes:
after bonding the SAW resonating plate, electrically connecting the first interconnection structure layer to the input electrode and the output electrode; or
before bonding the SAW resonating plate, forming a first redistribution layer and a first pad on the first interconnection structure layer; and
after bonding the SAW resonating plate, electrically connecting the first pad to the input electrode and the output electrode, such that the input electrode and the output electrode are electrically connected to the control circuit through the first pad and the first redistribution layer.

Optionally, facing the surface of the SAW resonating plate towards the base, such that the SAW resonating plate is bonded to the base and seals the cavity includes:
forming an adhesion structure on the surface of the base and at the periphery of the cavity; and
adhering the SAW resonating plate to the base through the adhesion structure.

Optionally, the adhesion structure includes a dry film.

Optionally, the cavity is formed in the dry film by exposure and development.

Optionally, the adhesion structure is formed by a patterned adhesive layer through screen printing.

Optionally, the integration method further includes: forming a second redistribution layer on a back of the base, the second redistribution layer being electrically connected to the input electrode, the output electrode and the control circuit.

Optionally, the second redistribution layer includes an Input/Output (I/O) pad.

Optionally, after the bonding, the integration method further includes:
forming a packaging layer, the packaging layer covering the base and the SAW resonating plate.

Optionally, the integration method further includes:
forming a third redistribution layer on the packaging layer, the third redistribution layer being electrically connected to the input electrode, the output electrode and the control circuit.

Optionally, both the input electrode and the output electrode include a pad.

According to another aspect of the present disclosure, an integration structure for a control circuit and an SAW filter is provided, which includes:
a base, the base being provided with a control circuit and a cavity; and
an SAW resonating plate, an input electrode and an output electrode being arranged on a surface of the SAW resonating plate, and the surface of the SAW resonating plate facing towards the base such that the SAW resonating plate is bonded to the base and seals the cavity, wherein
the control circuit is electrically connected to the input electrode and the output electrode.

Optionally, the base includes a substrate and a first dielectric layer formed on the substrate; and the cavity is formed in the first dielectric layer; or,
the base and the SAW resonating plate are bonded through an adhesion structure, and the cavity is formed in the adhesion structure.

Optionally, the adhesion structure is a dry film.

Optionally, the substrate includes one of an SOI substrate, a silicon substrate, a germanium substrate, a germanium silicate substrate and a gallium arsenide substrate.

Optionally, the control circuit includes a device structure and a first interconnection structure layer electrically connected to the device structure, the first interconnection structure layer being located on the first dielectric layer, and electrically connected to the input electrode and the output electrode.

Optionally, the device stricture includes an MOS device.

Optionally, a first redistribution layer and a first pad are formed on the base, the first pad being electrically connected to the input electrode and the output electrode, such that the input electrode and the output electrode are electrically connected to the control circuit through the first pad and the first redistribution layer.

Optionally, the integration structure further includes a second redistribution layer formed on a back of the base, the second redistribution layer being electrically connected to the input electrode, the output electrode and the control circuit.

Optionally, the second redistribution layer includes an I/O pad.

Optionally, the integration structure further includes a packaging layer, the packaging layer covering the base and the SAW resonating plate.

Optionally, the integration structure further includes a third redistribution layer formed on the packaging layer, the third redistribution layer being electrically connected to the input electrode, the output electrode and the control circuit.

Optionally, both the input electrode and the output electrode include a pad.

The present disclosure has the following beneficial effects: the present disclosure implements the control of the control circuit on the SAW filter by forming the control circuit and the cavity, required by the SAW filter, on the base, and then mounting the existing SAW resonating plate in the cavity, and thus may avoid the problems of the complex electrical connection process, large insertion loss and the like due to a fact that the existing SAW filter is integrated to the PCB as a discrete device, has the high level of integration, and reduces the process cost.

The present disclosure has other characteristics and advantages. These characteristics and advantages will become apparent from the accompanying drawings and following specific embodiments incorporated into the specification, or will be described in detail in the accompanying drawings and following specific embodiments incorporated into the specification. The accompanying drawings and the specific embodiments serve to explain a specific principle of the present disclosure.

### BRIEF DESCRIPTION OF THE DRAWINGS

By describing the exemplary embodiments of the present disclosure below in more detail in combination with the accompanying drawings, the above and other objectives, characteristics and advantages of the present disclosure will be more apparent. In the exemplary embodiments of the present disclosure, the same reference sign typically represents the same component.

FIG. 1 to FIG. 7 respectively show each process of an integration method for a control circuit and an SAW filter according to a first embodiment of the present disclosure,

FIG. 8 to FIG. 10 respectively show each process of an electrical connection of an SAW resonating plate in an integration method for a control circuit and an SAW filter according to a second embodiment of the present disclosure.

In the figures:

101—silicon substrate, 102—insulating layer, 103—top silicon layer, 201—source, 202—drain, 203—gate, 204—gate dielectric layer, 301—piezoelectric plate, 302—comb electrode, 401—first dielectric layer, 402—cavity, 403—packaging layer, 404—first conductive post, 405—first wiring layer, 406—first redistribution layer, 407—first pad, 408—adhesion structure, 409—third redistribution layer, 410—second conductive post, 411—I/O pad, 501—third conductive post, 502—second wiring layer, and 503—third redistribution layer.

### DESCRIPTION OF THE EMBODIMENTS

The present disclosure will be described below in more detail with reference to the accompanying drawings, Although the preferred embodiments of the present disclosure are shown in the accompanying drawings, it should be understood that the present disclosure may be implemented in various forms and should not be limited by the embodiments elaborated herein. Rather; these embodiments are provided so that the present disclosure will be thorough and complete, and the scope of the present disclosure can be fully conveyed to a person skilled in the art.

In order to solve the problems of the complex wiring, large insertion loss and the like of the existing SAW filter during packaging and integration, the embodiments of the present disclosure provide an integration method and integration structure for a control circuit and an SAW filter.

The integration method for the control circuit and the SAW filter according to the embodiments of the present disclosure includes: a base is provided, the base being provided with a control circuit: a cavity is formed on the base; an SAW resonating plate is provided, an input electrode and an output electrode being arranged on a surface of the SAW resonating plate; the surface of the SAW resonating plate faces towards the base, such that the SAW resonating plate is bonded to the base and seals the cavity; and the control circuit is electrically connected to the input electrode and the output electrode.

The integration method according to the embodiments of the present disclosure implements the control of the control circuit on the SAW filter by forming the control circuit and the cavity, required by the SAW filter, on the base, and then mounting the existing SAW resonating plate in the cavity, and thus may avoid the problems of the complex electrical connection process, large insertion loss and the like due to a fact that the existing SAW filter is integrated to the PCB as a discrete device, has the high level of integration, and reduces the process cost.

In order to understand the above objectives, characteristics and advantages of the present disclosure more clearly, the specific embodiments of the present disclosure will be described below in detail in combination with the accompanying drawings. When the embodiments of the present disclosure are detailed, the exemplary drawings are not partially amplified according to a general proportion for the ease of description. Moreover, the schematic diagrams are merely exemplary, and should not limit the scope of protection of the present disclosure herein. Additionally, three-dimensional spatial sizes on the length, width and length should be included in actual manufacture.

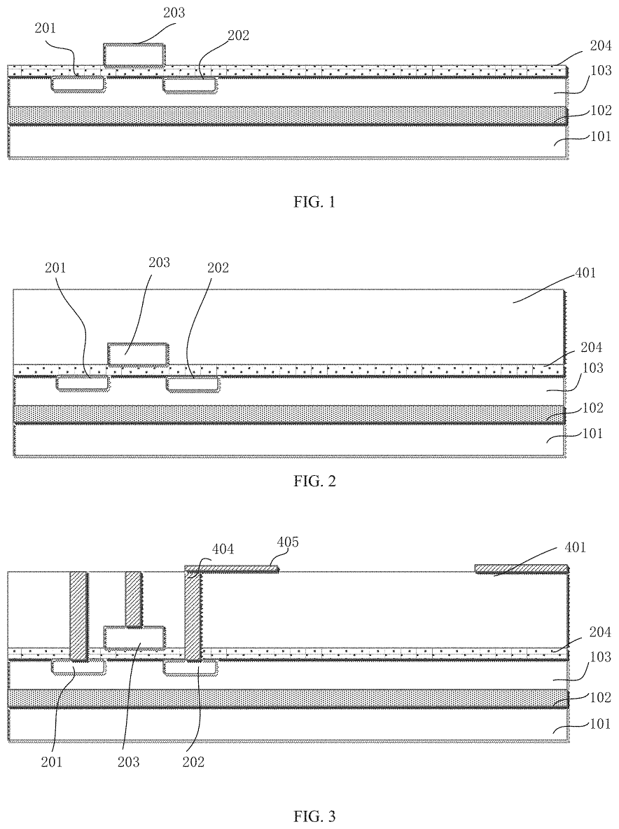

FIG. 1 to FIG. 7 respectively show each process of an integration method for a control circuit and an SAW filter according to a first embodiment of the present disclosure. The integration method includes the following steps:

S1: referring to FIG. 1 to FIG. 4, a base is provided, the base being provided with a control circuit.

Referring to FIG. 1 and FIG. 2, in the embodiment, the base includes a substrate and a first dielectric layer 401 formed on the substrate. Optionally, the substrate includes one of an SOI substrate, a silicon substrate, a germanium substrate, a germanium silicate substrate and a gallium arsenide substrate. The person skilled in the art may also select the type of the substrate according to the control circuit formed on the substrate. In the embodiment, the substrate is the SOI substrate.

The SOI may be of a double-layer structure of the insulating silicon substrate and the top monocrystalline silicon layer, and may also be of a sandwich structure with the insulating layer as the intermediate layer (called the buried layer). During device manufacture, only the top thin silicon layer serves as the device manufacturing layer to form structures like the source, drain and channel region, while the silicon substrate only takes the support effect. In the sandwich structure, the buried layer separates the device manufacturing layer from the silicon substrate electrically, so as to reduce the influence of the silicon substrate on the device performance. The SOI has the advantages of reducing the parasitic capacitance, reducing the power consumption, eliminating the latch-up effect and the like in device performance. At present, the SOI substrate is typically obtained with the Smart-Cut™ process. The SOI substrate is used in the embodiment so as to exert the above advantages of the SOI.

Still referring to FIG. 1, in the embodiment, the 501 substrate includes a silicon substrate 101, an insulating layer 102 located on the silicon substrate 101 and a top silicon layer 103 located on the insulating layer 102, or the SOI substrate may be of a double-layer structure of the insulating layer and the top silicon layer.

Still referring to FIG. 2, the first dielectric layer 401 is a low-K dielectric material layer such as a silicon oxide layer. The first dielectric layer 401 may be formed by Chemical Vapor Deposition (CVF). The first dielectric layer 401 is configured to form the cavity 402 that is required by the work of the SAW filter.

In the embodiment, the control circuit includes a device structure and a first interconnection structure layer electrically connected to the device structure, the first interconnection structure layer being located on the first dielectric layer 401. The device structure includes an MOS device such as an MOS switch. The MOS switch may be the nMOS or pMOS switch. Still referring to FIG. 1, the MOS switch includes a source 201, a drain 202 and a gate 203, and further includes a gate dielectric layer 204 or a gate dielectric region on a surface of the top silicon layer 103 for isolating the source, drain and gate. The source 201 and the drain 202 may be formed in the top silicon layer with the Low Dose Drain (LDD) process and Source/Drain Implantation (S/D IMP).

Referring to FIG. 3, optionally, the first interconnection structure layer includes a first conductive post 404 and a first wiring layer 405 that are electrically connected to the device structure in sequence. In the embodiment, a first through hole penetrating through the first dielectric layer 401 and a first trench provided on a surface of the first dielectric layer are first formed; and then, an electrical connection material is filled in the first through hole and the first trench to form the first conductive post 404 and the first wiring layer 405.

The first through hole penetrating through the first dielectric layer 401 and the first trench provided on the surface of the first dielectric layer 401 may be formed by etching. The first trench defines the path of local interconnection metal. Then, the electrical connection material is filled in the first through hole and the first trench by deposition (for example, sputtering). The electrical connection material is preferably copper, tungsten, titanium, etc. In the embodiment, as the gate dielectric layer 204 is formed on the top silicon layer 103, the first through hole further penetrates through the gate dielectric layer 204.

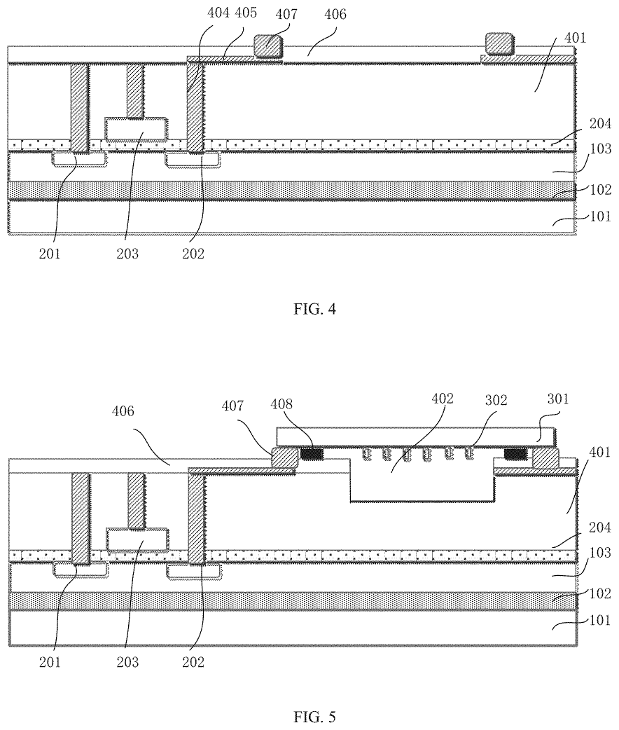

Referring to FIG. 4, optionally, in a case where the first interconnection structure layer cannot be directly and electrically connected to the input electrode and the output electrode, a first redistribution layer 406 and a first pad 407 are formed on the base, the first redistribution layer 406 being electrically connected to the first wiring layer 405 of the control circuit. The first redistribution layer 406 may be formed by deposition; and similarly, the first pad 407 is formed by etching and deposition.

S2: referring to FIG. 5, a cavity is formed on the base.

Referring to FIG. 5, in the embodiment, the cavity 402 that is sunken inwards is formed on the first dielectric layer 401 by etching.

Still referring to FIG. 5, optionally, an adhesion structure 408 is formed on a surface of the base, so as to implement subsequent bonding between the SAW resonating plate and the base. The adhesion structure 408 may be a dry film or another type of chip connection film. Optionally, before the cavity is formed on the base, in heating and pressurizing conditions, a layer of dry film is adhered on the surface of the base, the dry film is then patterned, and by performing exposure and development on the dry film, etching the first dielectric layer 401 and forming the cavity 402 that is sunken inwards on the base, the retained dry film portion is formed into the adhesion structure 408. Optionally, the adhesion structure 408 is formed by a patterned adhesive layer through screen printing. The adhesive layer is typically made of epoxy resin. With the screen printing method, the patterned adhesive layer may be directly formed on the surface of the base, and there is no need for photoetching, exposure, development and other steps to implement the patterning.

Optionally, when the first redistribution layer 406 is formed on the base, before the cavity is formed on the base, in the heating and pressurizing conditions, a layer of dry film is adhered on a surface of the first redistribution layer 406, then the dry film is patterned, and by performing exposure and development on the dry film, etching the first dielectric layer 401 and forming the cavity 402 that is sunken inwards on the base, the retained dry film portion is formed into the adhesion structure 408. Optionally, when the cavity 402 has a small depth, the cavity 402 may be formed in the adhesion structure 408.

S3: referring to FIG. 5, an SAW resonating plate is provided, an input electrode and an output electrode being arranged on a surface of the SAW resonating plate.

Referring to FIG. 5, the SAW resonating plate includes a piezoelectric plate 301, a pair of comb electrodes 302 arranged on the piezoelectric plate 301, the input electrode and the output electrode (not shown), the input electrode and the output electrode being respectively and electrically connected to the pair of comb electrodes 302, Optionally, both the input electrode and the output electrode include a pad. The pair of comb electrodes 302 respectively serve as a transmitting transducer and a receiving transducer. The transmitting transducer converts the electrical signal into the SAW to be propagated on the surface of the piezoelectric plate 301. With a certain delay, the receiving transducer converts the acoustic signal into the electrical signal to output. The filtration process is implemented in conversion from the electrical signal to the acoustic signal and from the acoustic signal to the electrical signal.

S4: referring to FIG. 5, the surface of the SAW resonating plate faces towards the base, such that the SAW resonating plate is bonded to the base and seals the cavity.

In the embodiment, the input electrode and the output electrode are located on the first surface of the piezoelectric plate 301, During bonding, the first surface faces towards the cavity 402, such that the SAW resonating plate is bonded to the base and seals the cavity 402.

Optionally, the annular adhesion structure 408 is formed on the surface of the base and at the periphery of the cavity 402. The piezoelectric plate 301 of the SAW resonating plate is adhered on the base through the adhesion structure 408, such that the SAW resonating plate is bonded to the base and seals the cavity 402. The piezoelectric plate 301 may be firmly fixed on the base through the adhesion structure 408.

S5: the control circuit is electrically connected to the input electrode and the output electrode.

It is mentioned in step S1 that the control circuit may include the device structure and the first interconnection structure layer electrically connected to the device structure, the first interconnection structure layer being located on the first dielectric layer 401. Correspondingly, electrically connecting the control circuit to the input electrode and the output electrode includes after the SAW resonating plate is bonded, the first interconnection structure layer is electrically connected to the input electrode and the output electrode.

Still referring to FIG. 5, optionally, the first redistribution layer 406 and the first pad 407 may be formed on the base; and correspondingly, electrically connecting the control circuit to the input electrode and the output electrode includes:

Before the SAW resonating plate is bonded, the first redistribution layer 406 and the first pad 407 are formed on the first interconnection structure layer.

After the SAW resonating plate is bonded, the first pad 407 is electrically connected to the input electrode and the output electrode, such that the input electrode and the output electrode are electrically connected to the control circuit through the first pad 407 and the first redistribution layer 406.

The integration for the control circuit and the SAW filter is implemented through the above steps S1 to S5. In the embodiment, the integration method may further include the following steps S6 and S7:

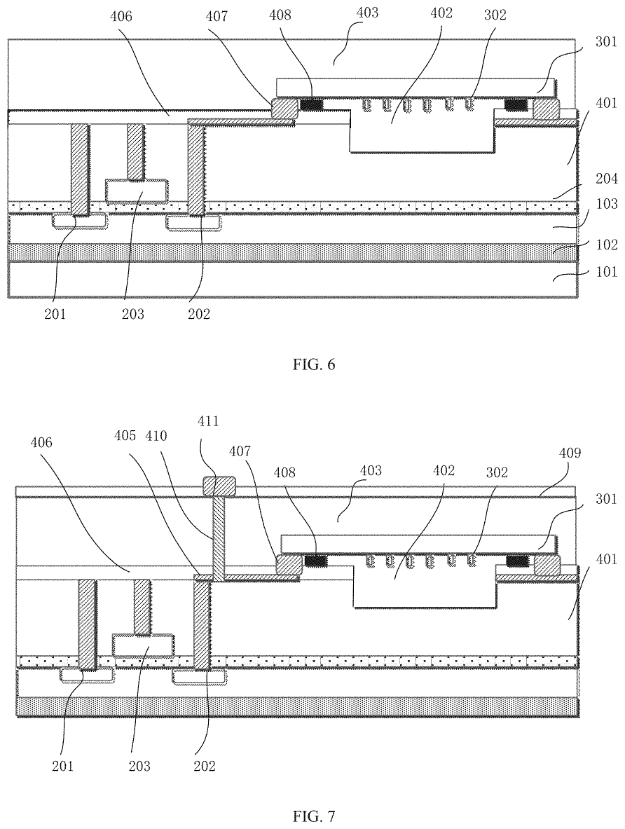

S6: referring to FIG. 6, a packaging layer 403 is formed, the packaging layer covering the base and the SAW resonating plate. The packaging layer 403 may be formed with a molding method. The material used by the molding may be epoxy resin.

S7: referring to FIG. 7, the silicon substrate 101 is removed to make the integration structure thin. In the embodiment, the silicon substrate 101 may be removed by Chemico-Mechanical Polishing (CMP).

S8: still referring to FIG. 7, a third redistribution layer 409 is formed on the packaging layer 403, the third redistribution layer 409 being electrically connected to the input electrode, the output electrode and the control circuit.

Specifically, a second through hole penetrating through the packaging layer 403 is formed, the electrical connection material is filled in the second through hole to form a second conductive post 410, and then the third redistribution layer 409 is formed on the packaging layer 403. The third redistribution layer 409 is electrically connected to the second conductive post 410. The third redistribution layer 409 further includes an I/O pad 411. Similarly, the second through hole may be formed by etching; and the electrical connection material (such as copper) is filled in the second through hole by deposition (for example, sputtering) to form the second conductive post 410. The I/O pad 411 may be connected to an external power supply.

The integration structure obtained in the embodiment is as shown in FIG. 7.

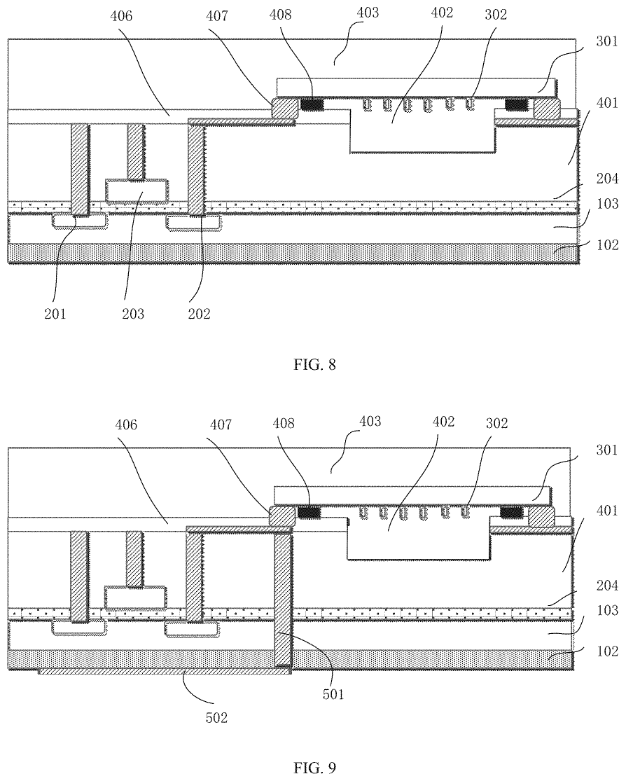

The integration method for the control circuit and the SAW filter according to the second embodiment of the present disclosure also includes the above steps S1 to S7, and the difference from the first embodiment lies in step S8. Referring to FIG. 8 to FIG. 10, the integration method according to the second embodiment of the present disclosure includes the following step after step S7:

A second redistribution layer 502 is formed on a back of the base, the second redistribution layer 502 being electrically connected to the input electrode, the output electrode and the control circuit.

Specifically, referring to FIG. 8 and FIG. 9, in the integration structure, in which the packaging layer 403 is formed and the silicon substrate 101 is removed, shown in FIG. 8, a third through hole penetrating through the insulating layer 102, the top silicon layer 103 and the first dielectric layer 401 is formed. The electrical connection material is filled in the third through hole to form a third conductive post 501. The third conductive post 501 is electrically connected to the first interconnection structure layer 405. A second wiring layer 502 is formed on the surface of the insulating layer, the second wiring layer 502 being electrically connected to the third conductive post 501.

The second redistribution layer 503 electrically connected to the second wiring layer 502 and the third conductive post 501 in sequence is formed on the surface of the insulating layer 102. The second redistribution layer 503 further includes the I/O pad 411.

The embodiments of the present disclosure further provide an integration structure for the control circuit and the SAW filter, which includes: a base, the base being provided with a control circuit and a cavity; and an SAW resonating plate, an input electrode and an output electrode being arranged on a surface of the SAW resonating plate, and the surface of the SAW resonating plate facing towards the base such that the SAW resonating plate is bonded to the base and seals the cavity; and the control circuit is electrically connected to the input electrode and the output electrode.

The integration structure according to the embodiments of the present disclosure implements the control on the SAW filter by forming the control circuit on the base, and thus may avoid the problems of the complex electrical connection process, large insertion loss and the like due to a fact that the existing SAW filter is integrated to the PCB as a discrete device, has the high level of integration, and reduces the process cost.

Referring to FIG. 7, the integration structure for the control circuit and the SAW filter according to the first embodiment of the present disclosure includes:
a base, the base being provided with a control circuit and a cavity 402; and
an SAW resonating plate, an input electrode and an output electrode being arranged on a surface of the SAW resonating plate, and the surface of the SAW resonating plate facing towards the base such that the SAW resonating plate is bonded to the base and seals the cavity 402.

The control circuit is electrically connected to the input electrode and the output electrode.

In the embodiment, the base includes a substrate and a first dielectric layer 401 formed on the substrate. The substrate is an SOI substrate. The SOI substrate includes an insulating layer 102 and a top silicon layer 103 located on the insulating layer 102.

The control circuit includes a device structure and a first interconnection structure layer electrically connected to the device structure. The device structure includes an MOS switch. The MOS switch includes a source 201 and a drain 202 formed in the top silicon layer 103 of the SOI substrate, and a gate dielectric layer 204 and a gate 203 formed on the top silicon layer 103.

The first interconnection structure layer is located on the first dielectric layer 401, and electrically connected to the input electrode and the output electrode. Specifically, the first interconnection structure layer includes a first conductive post 404 and a first wiring layer 405 that are electrically connected to the device structure in sequence. The cavity 402 is formed in the first dielectric layer 401.

The SAW resonating plate includes a piezoelectric plate 301, a pair of comb electrodes 302 arranged on the piezoelectric plate 301, the input electrode and the output electrode, the input electrode and the output electrode being respectively and electrically connected to the pair of comb electrodes 302. Optionally, both the input electrode and the output electrode include a pad.

In the embodiment, the integration structure further includes a first redistribution layer 406 and a first pad 407 that are formed on the base. The first pad 407 is electrically connected to the input electrode and the output electrode, such that the input electrode and the output electrode are electrically connected to the control circuit through the first pad 407 and the first redistribution layer 406.

The base and the SAW resonating plate are bonded through an annular adhesion structure 408. The adhesion structure 408 is disposed on the first redistribution layer 406 and at the periphery of the cavity 402, Optionally, the adhesion structure 408 is a dry film or an adhesive layer formed through screen printing, or another chip connection film.

In the embodiment, the integration structure further includes a packaging layer 403, the packaging layer 403 covering the base and the SAW resonating plate.

In the embodiment, the integration structure further includes a third redistribution layer 409, electrically connected to the input electrode, the output electrode and the control circuit. Specifically, the third redistribution layer 409 is electrically connected to a second conductive post 410 penetrating through the packaging layer 403. The third redistribution layer 409 further includes an I/O pad 411.

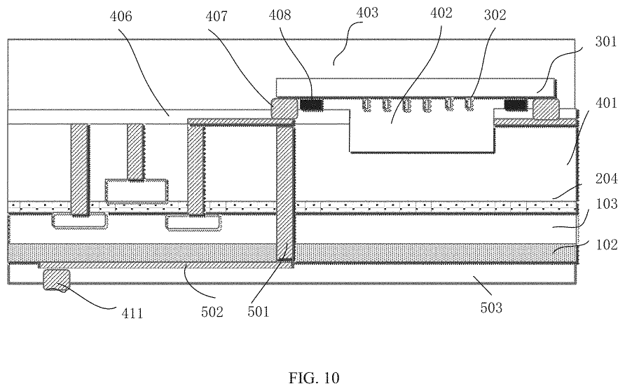

Referring to FIG. 10, the difference of the integration structure for the control circuit and the SAW filter according to the second embodiment of the present disclosure from the first embodiment lies in that external I/O electrical connection is performed from the back of the base.

Referring to FIG. 10, the integration structure for the control circuit and the SAW filter according to the second embodiment of the present disclosure includes:
a base, the base being provided with a control circuit and a cavity; and
an SAW resonating plate, an input electrode and an output electrode being arranged on a surface of the SAW resonating plate, and the surface of the SAW resonating plate facing towards the base such that the SAW resonating plate is bonded to the base and seals the cavity 402.

The control circuit is electrically connected to the input electrode and the output electrode.

In the embodiment, the base includes a substrate and a first dielectric layer 401 formed on the substrate. The substrate is an SOI substrate. The SOI substrate includes an insulating layer 102 and atop silicon layer 103 located on the insulating layer 102.

The control circuit includes a device structure and a first interconnection structure layer electrically connected to the device structure. The device structure includes an MOS switch. The MOS switch includes a source 201 and a drain 202 formed in the top silicon layer 103 of the SOI substrate, and a gate dielectric layer 204 and a gate 203 formed on the top silicon layer 103.

The first interconnection structure layer is located on the first dielectric layer, and electrically connected to the input electrode and the output electrode. Specifically, the first interconnection structure layer includes a first conductive post 404 and a first wiring layer 405 that are electrically connected to the device structure in sequence. The cavity 402 is formed in the first dielectric layer 401.

The SAW resonating plate includes a piezoelectric plate 301, a pair of comb electrodes 302 arranged on the piezoelectric plate 301, the input electrode and the output electrode (not shown), the input electrode and the output electrode being respectively and electrically connected to the pair of comb electrodes 302. Optionally, both the input electrode and the output electrode include a pad.

In the embodiment, the integration structure further includes a first redistribution layer 406 and a first pad 407 that are formed on the base. The first pad 407 is electrically connected to the input electrode and the output electrode, such that the input electrode and the output electrode are electrically connected to the control circuit through the first pad 407 and the first redistribution layer 406.

The base and the SAW resonating plate are bonded through an annular adhesion structure 408. The adhesion structure 408 is disposed on the first redistribution layer 406 and at the periphery of the cavity 402. Optionally, the adhesion structure 408 is a dry film or a chip connection film.

In the embodiment, the integration structure further includes a packaging layer 403, the packaging layer 403 covering the base and the SAW resonating plate.

In the embodiment, the integration structure further includes a second redistribution layer 503 formed on a back of the base, the second redistribution layer 503 being electrically connected to the input electrode, the output electrode and the control circuit. Specifically, the second redistribution layer 503 is disposed on a surface of the insulating layer 102, and electrically connected to a third conductive post 501 penetrating through the base and a second wiring layer 502 disposed on the surface of the insulating layer. The third conductive post 501 is electrically connected to the first interconnection structure layer 405. The second redistribution layer 503 further includes the I/O pad 411.

The embodiments of the present disclosure have been described above, and the foregoing description is illustrative, not limiting, and not limited to the disclosed embodiments. Numerous modifications and changes will be apparent to those skilled in the art without departing from the scope and spirit of the illustrated embodiments.

1-27. (canceled)

28. An integration method for a control circuit and a surface acoustic wave (SAW) filter, comprising:
providing a base, the base being provided with a control circuit;
forming a cavity on the base;
providing an SAW resonating plate, an input electrode and an output electrode being arranged on a surface of the SAW resonating plate;
facing the surface of the SAW resonating plate towards the base, such that the SAW resonating plate is bonded to the base and seals the cavity; and
electrically connecting the control circuit to the input electrode and the output electrode.

29. The integration method according to claim 28, wherein the base comprises a substrate and a first dielectric layer formed on the substrate; and
forming the cavity on the base comprises:
forming the cavity in the first dielectric layer.

30. The integration method according to claim 29, wherein the substrate comprises one of a Silicon-on-Insulator (SOI) substrate, a silicon substrate, a germanium substrate, a germanium silicate substrate and a gallium arsenide substrate.

31. The integration method according to claim 29, wherein the control circuit comprises a device structure and a first interconnection structure layer electrically connected to the device structure, the first interconnection structure layer being located on the first dielectric layer, and electrically connected to the input electrode and the output electrode, and
wherein the device structure comprises a Metal Oxide Semiconductor (MOS) device.

32. The integration method according to claim 31, wherein electrically connecting the control circuit to the input electrode and the output electrode comprises:
after bonding the SAW resonating plate, electrically connecting the first interconnection structure layer to the input electrode and the output electrode; or
before bonding the SAW resonating plate, forming a first redistribution layer and a first pad on the first interconnection structure layer; and
after bonding the SAW resonating plate, electrically connecting the first pad to the input electrode and the output electrode, such that the input electrode and the output electrode are electrically connected to the control circuit through the first pad and the first redistribution layer.

33. The integration method according to claim 31, wherein facing the surface of the SAW resonating plate towards the base, such that the SAW resonating plate is bonded to the base and seals the cavity comprises:
forming an adhesion structure on the surface of the base and at the periphery of the cavity; and
adhering the SAW resonating plate to the base through the adhesion structure.

34. The integration method according to claim 33, wherein the adhesion structure comprises a dry film, and
wherein the cavity is formed in the dry film by exposure and development.

35. The integration method according to claim 33, wherein the adhesion structure is formed by a patterned adhesive layer through screen printing.

36. The integration method according to claim 28, further comprising: forming a second redistribution layer on a back of the base, the second redistribution layer being electrically connected to the input electrode, the output electrode and the control circuit,
wherein the second redistribution layer comprises an Input/Output (I/O) pad.

37. The integration method according to claim 28, after the bonding, further comprising:
forming a packaging layer, the packaging layer covering the base and the SAW resonating plate; and
forming a third redistribution layer on the packaging layer, the third redistribution layer being electrically connected to the input electrode, the output electrode and the control circuit.

38. The integration method according to claim 28, wherein both the input electrode and the output electrode include a pad.

39. An integration structure for a control circuit and a Surface Acoustic Wave (SAW) filter, comprising:
a base, the base being provided with a control circuit and a cavity; and
an SAW resonating plate, an input electrode and an output electrode being arranged on a surface of the SAW resonating plate, and the surface of the SAW resonating plate facing towards the base such that the SAW resonating plate is bonded to the base and seals the cavity,
wherein the control circuit is electrically connected to the input electrode and the output electrode.

40. The integration structure according to claim 39, wherein the base comprises a substrate and a first dielectric layer formed on the substrate; and the cavity is formed in the first dielectric layer; or
the base and the SAW resonating plate are bonded through an adhesion structure, and the cavity is formed in the adhesion structure.

41. The integration structure according to claim 40, wherein the adhesion structure is a dry film; and/or
the substrate comprises one of a Silicon-on-Insulator (SOI) substrate, a silicon substrate, a germanium substrate, a germanium silicate substrate and a gallium arsenide substrate.

42. The integration structure according to claim 40, wherein the control circuit comprises a device structure and a first interconnection structure layer electrically connected to the device structure, the first interconnection structure layer being located on the first dielectric layer, and electrically connected to the input electrode and the output electrode, and
wherein the device structure comprises a Metal Oxide Semiconductor (MOS) device.

43. The integration structure according to claim 42, wherein a first redistribution layer and a first pad are formed on the base, the first pad being electrically connected to the input electrode and the output electrode, such that the input electrode and the output electrode are electrically connected to the control circuit through the first pad and the first redistribution layer.

44. The integration structure according to claim 39, further comprising a second redistribution layer formed on a back of the base, the second redistribution layer being electrically connected to the input electrode, the output electrode and the control circuit,
wherein the second redistribution layer comprises an Input/Output (I/O) pad.

45. The integration structure according to claim 39, further comprising a packaging layer, the packaging layer covering the base and the SAW resonating plate.

46. The integration structure according to claim 45, further comprising a third redistribution layer formed on the packaging layer, the third redistribution layer being electrically connected to the input electrode, the output electrode and the control circuit.

47. The integration structure according to claim 39, wherein both the input electrode and the output electrode include a pad.
